(19) United States
(12) Patent Application Publication
(10) Pub. No.: US 2014/0071641 A1
(43) Pub. Date: Mar. 13, 2014

(54) VOLTAGE CONVERTER AND POWER SUPPLY DEVICE USING THE SAME

(71) Applicants: HON HAI PRECISION INDUSTRY CO., LTD., New Taipei (TW); HONG FU JIN PRECISION INDUSTRY (ShenZhen) Co., LTD., Shenzhen (CN)

(72) Inventors: ZHEN-YU WANG, Shenzhen (CN); CHANG-SHEN CHANG, New Taipei (TW); BEN-FAN XIA, Shenzhen (CN)

(73) Assignees: HON HAI PRECISION INDUSTRY CO., LTD., New Taipei (TW); HONG FU JIN PRECISION INDUSTRY (ShenZhen) Co., LTD., Shenzhen (CN)

(21) Appl. No.: 14/016,391

(22) Filed: Sep. 3, 2013

(30) Foreign Application Priority Data
Sep. 7, 2012 (CN) 201210328890X

(51) Int. Cl. H05K 5/00

(52) U.S. Cl. CPC H05K 5/0065
USPC 361/752; 361/748

(57) ABSTRACT

A power supply device includes a laptop battery and a voltage converter secured to the laptop battery. The laptop battery includes a first connecting portion and a first interface for outputting a first voltage. The voltage converter includes a housing, a second connecting portion formed in the housing and a circuit board secured to the housing. The circuit board includes a second interface, a first converting unit and a third interface. The first connecting portion is detachably coupled to the second portion to secure the voltage converter to the laptop battery. The second interface is electronically connected to the first interface so as to receive the first voltage when the first connecting portion is coupled to the second connecting portion. The first converting unit converts the first voltage to the second voltage and outputs the second voltage through the third interface.

### BACKGROUND

1. Technical Field

The present disclosure relates to a voltage converter and a power supply device using the voltage converter.

2. Description of Related Art

A laptop battery is generally rechargeable, and has a capacity of more than 4000 mAh. The laptop battery includes an interface matching with a corresponding laptop, but not matching with other portable electronic devices such as mobile phone and digital camera. Further, the laptop battery outputs a voltage of 12V, but the mobile phone or the digital camera needs a voltage lower than 12V. Therefore, the laptop battery cannot be directly used for powering the other electronic devices different from the laptop.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric view of a power supply device; the power supply device includes a laptop battery and a voltage converter.

FIG. 2 is an exploded view of the power supply device in FIG. 1.

FIG. 3 is an exploded view of the voltage converter in FIG. 2.

FIG. 4 is an isometric view of the voltage converter of FIG. 2 viewed from another aspect.

FIG. 5 is a function block diagram of the voltage converter in FIG. 3.

### DETAILED DESCRIPTION

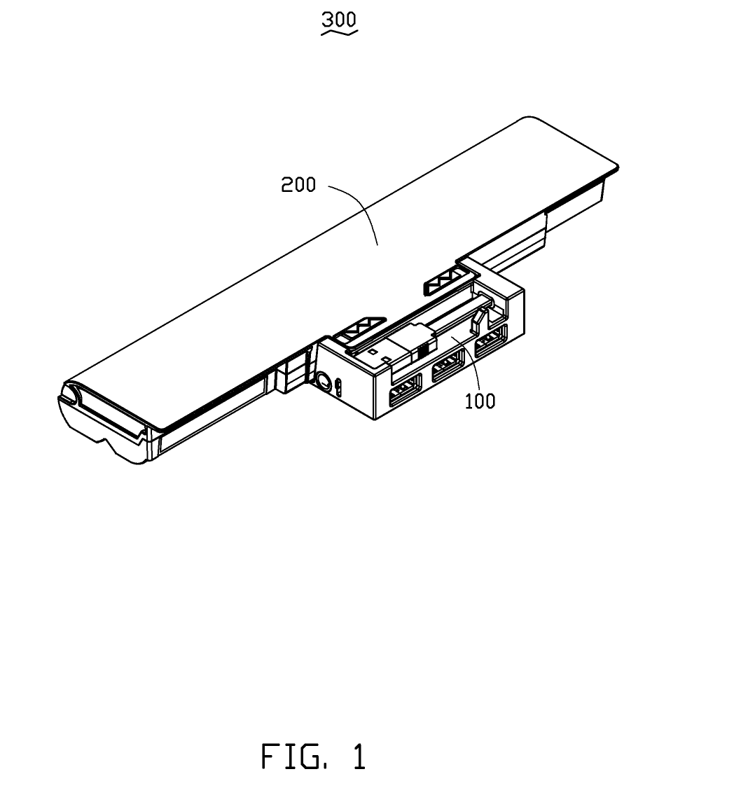

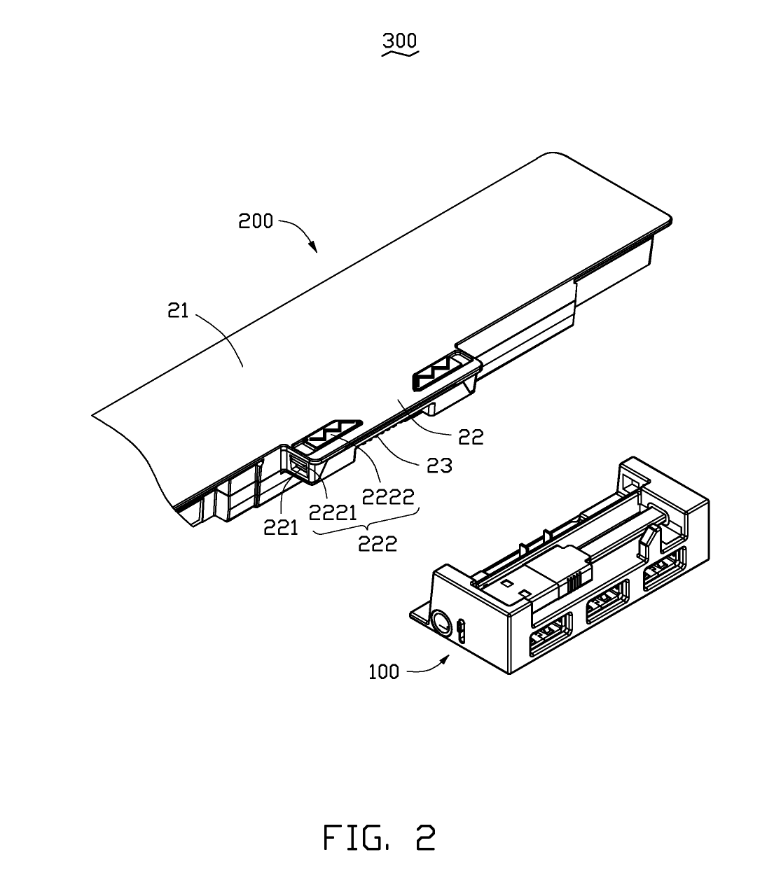

FIGS. 1 and 2 show a power supply device 300 of an embodiment. The power supply device 300 includes a laptop battery 200 and a voltage converter 100. The laptop battery 200 is detachably coupled to a laptop (not shown) or the voltage converter 100 for electronically connected to the laptop or the voltage converter 100. The laptop battery 200 outputs a first voltage to power the laptop.

The voltage converter 100 can also be detachably and electrically connected to other types of portable electronic devices (not shown) which are different from the laptop and driven by a second voltage lower than the first voltage. The portable electronic devices of other types may be mobile phones, digital cameras or the like which need a voltage supply lower than the first voltage. When the voltage converter 100 is electrically connected to the laptop battery 200 and a portable electronic device of other types, the voltage converter 100 is configured to convert the first voltage to a second voltage for powering the portable electronic device. The voltage converter 100 is further detachably and electrically connected to an external power supply (not shown) which provides with a third voltage. When the voltage converter 100 is electrically connected to the laptop battery 200 and the power supply, the voltage converter 100 is configured to convert the third voltage to a fourth voltage lower than the third voltage for charging the laptop battery 200.

The laptop battery 200 includes a main body 21, a first connecting portion 22 located on a side of the main body 21, and a first interface 23 located on the first connecting portion 22. The first connecting portion 22 protrudes from the side of the main body 21. The first connecting portion 22 includes two receiving cavities 221 and two hook members 222 corresponding to the two receiving cavities 221. The hook member 222 includes a hook 2221 and a push button 2222 fixed to the hook 2221. The hook 2221 is slidably received in the corresponding receiving cavity 221. The push button 2222 is exposed out of the corresponding receiving cavity 221. The hook 2221 slides out of or into the corresponding receiving cavity 221 by manually pushing the push button 2222. The first interface 23 is located between the two receiving cavities 221. The main body 21 outputs the first voltage through the first interface 23.

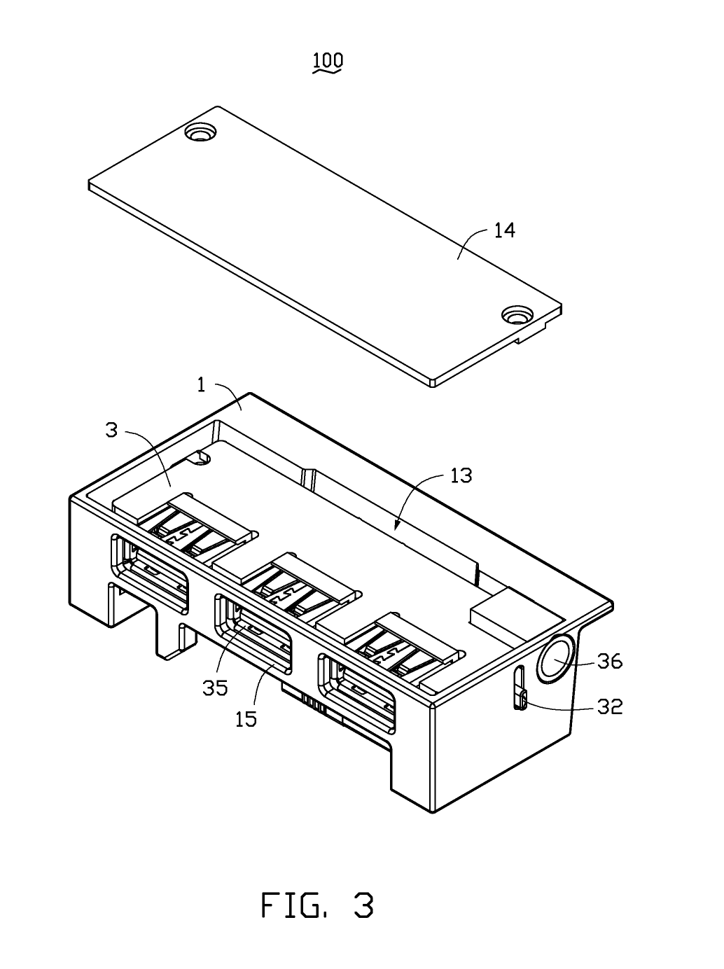

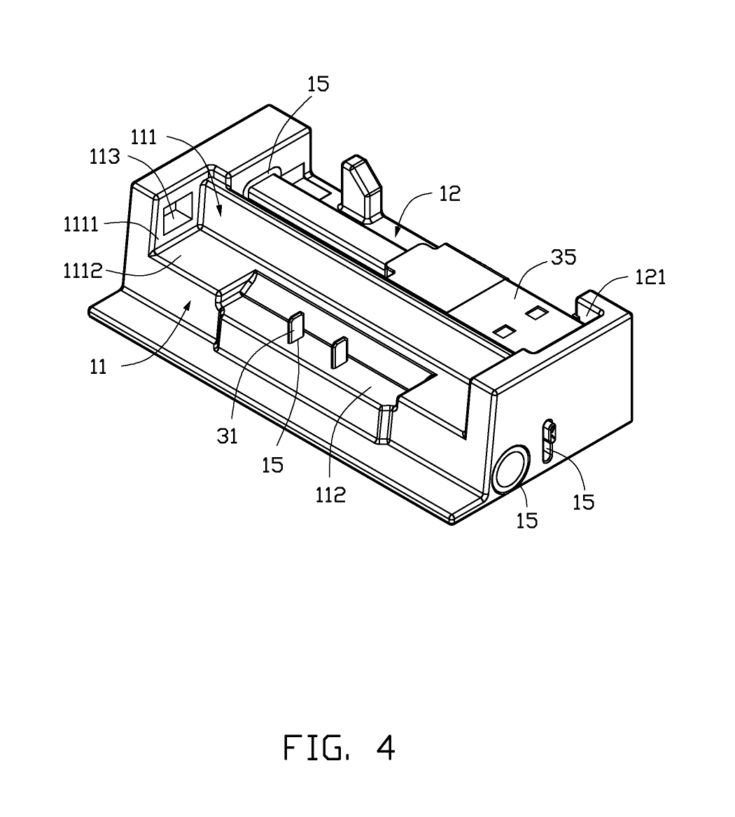

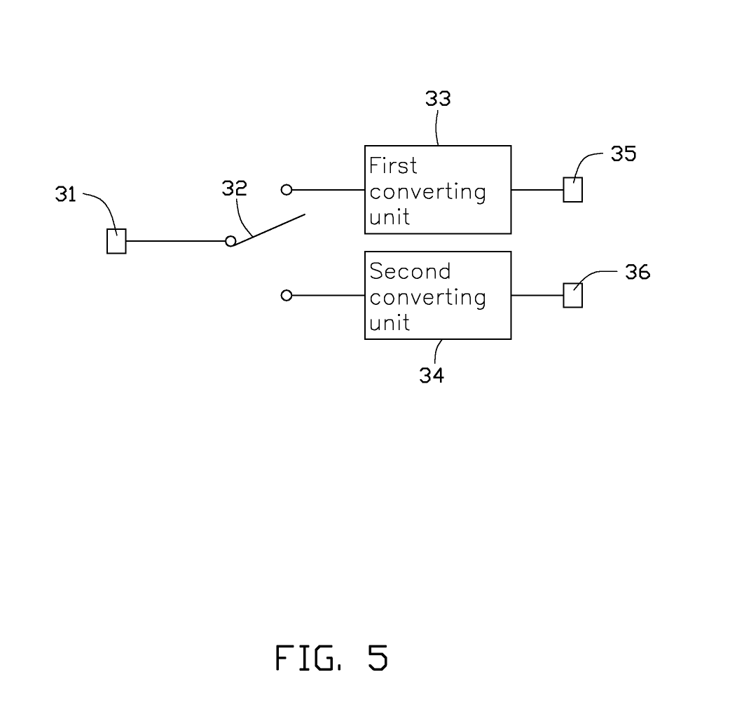

Referring to FIGS. 3-5 show that the voltage converter 100 is detachably fixed to the first connecting portion 22 to electrically connect to the first interface 23. The voltage converter 100 includes a housing 1, and a circuit board 3 received in the housing 1.

The housing 1 includes a second connecting portion 11, an engaging groove 12, a receiving space 13 for receiving the circuit board 3, a cover 14, and several through holes 15 communicating with the receiving space 13.

The second connecting portion 11 defines a recess 111. The recess 111 is defined in a side of the housing 1 to form two opposite sidewalls 1111 and a first bottom surface 1112 connected between the two sidewalls 1111. A second bottom surface 112 is recessed from the first bottom surface 1112. The two receiving grooves 113 are defined in the two sidewalls 1111. The engaging groove 12 is defined in the opposite side of the housing 1. The engaging groove 12 includes a clamping member 121. The cover 14 is detachably fixed to the housing 1 to cover the receiving space 13.

The circuit board 3 includes a voltage converting circuit 30. The voltage converting circuit 30 includes a second interface 31, a selector switch 32, a first converting unit 33, a second converting unit 34, several third interfaces 35 and a fourth interface 36. The second interface 31 is connected to one terminal of the selector switch 32. The other terminal of the selector switch 32 is selectively connected to the third interface 35 through the first converting unit 33, or connected to the fourth interface 36 through the second converting unit 34. When the circuit board 3 is received in the housing 1, the second interface 31, the selector switch 32, the several third interfaces 35, and the fourth interface 36 are exposed out of the housing 1 through the several through holes 15. One of the third interfaces 35 is receivable in the engaging groove 12, and is configured to be detachably clamped by the clamping member 121.

The second interface 31 is electronically connected to the first interface 23 when the voltage converter 100 is fixed to the laptop battery 200. The second interface 31 is configured to receive the first voltage from the first interface 23, or output the fourth voltage to the first interface 23. The several third interfaces 35 are configured to output the second voltage. The several third interfaces 35 are standard USB interface. The fourth interface 36 is configured to receive the third voltage from the external power supply. When the selector switch 32 is electronically connected to the first converting unit 33, the first converting unit 33 is configured to convert the first voltage received from the second interface 31 to the second voltage, and output the second voltage through of the several third interfaces 35 for powering the other types of portable electronic devices. The second voltage can be 3V, 4.2V, 5V, 8.4V and so on. When the selector switch 32 is electronically connected to the second converting unit 34, the second converting unit 34 is configured to convert the third voltage received from the fourth interface 36 to the fourth voltage, and output the fourth voltage through the second interface 31 for charging the laptop battery 200.

When the power supply device 300 is assembled, the voltage converter 100 is fixed to the laptop battery 200 by engaging the two hook members 2221 in the two corresponding receiving grooves 113. At this time, the first connecting portion 22 receives in the second connecting portion 11. The first interface 23 and the second interface 31 are hidden by the first connecting portion 22 and the second connecting portion 11. The second interface 31 is electronically connected to the first interface 23. The voltage converter 100 can convert the first voltage provided by the laptop battery 200 to the second voltage for powering the other types of portable electronic devices such as mobile phone and digital camera. Thus, the power supply device 300 is used as a mobile power which can directly power the other types of electronic devices.

Even though relevant information and the advantages of the present embodiments have been set forth in the foregoing description, together with details of the functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. A voltage converter for converting a first voltage provided by a laptop battery to a second voltage, the laptop battery comprising a first connecting portion and a first interface for outputting the first voltage, the voltage converter comprising:
a housing, comprising a second connecting portion;
a circuit board secured to the housing, the circuit board comprises a second interface, a first converting unit and a third interface;
wherein the first connecting portion is detachably coupled to the second connecting portion to secure the voltage converter to the laptop battery, the second interface is electronically connected to the first interface so as to receive the first voltage when the first connecting portion is coupled to the second connecting portion, the first converting unit is configured to convert the first voltage to the second voltage and output the second voltage through the third interface.

2. The power supply device of claim 1, wherein when the voltage converter is secured to the laptop battery, the first connecting portion and the second connecting portion are attached together to hide the first interface and the second interface.

3. The power supply device of claim 1, wherein the first connecting portion comprises a hook member, the second connecting portion comprises a receiving groove corresponding to the hook member, the voltage converter is secured to the laptop battery when the hook member is engagingly received in the receiving groove.

4. The power supply device of claim 1, wherein the housing defines an engaging groove with a clamping member, the third interface is receivable in the engaging groove and is configured to be detachably clamped by the clamping member.

5. The power supply device of claim 1, wherein the second voltage is lower than the first voltage.

6. A voltage converter for being electrically connected to a laptop battery and an electronic device, or electrically connected to the laptop battery and a power supply, the voltage converter comprising:
a circuit board, comprising a first converting unit and a second converting unit;
wherein when the voltage converter is electrically connected to the laptop battery and the electronic device, the first converting unit is configured to convert a first voltage provided by the laptop battery to a second voltage for powering the electronic device;
when the voltage converter is electrically connected to the laptop battery and the power supply, the second converting unit is configured to convert a third voltage provided by the power supply to a fourth voltage for charging the laptop battery.

7. The power supply device of claim 6, wherein the circuit board further comprises a selector switch, when the voltage converter is electrically connected to the laptop battery and the electronic device, the selector switch is electrically connected to the first converting unit; when the voltage converter is electrically connected to the laptop battery and the power supply, the selector switch is electrically connected to the second converting unit.

8. The power supply device of claim 6, wherein the second voltage is lower than the first voltage.

9. The power supply device of claim 6, wherein the fourth voltage is lower than the third voltage.

10. A power supply device, comprising:
a laptop battery, comprising a first connecting portion, and a first interface for outputting a first voltage;
a voltage converter, comprising a housing, a second connecting portion formed in the housing, and a circuit board secured to the housing, the circuit board comprising a second interface, a first converting unit, and a third interface;
wherein the first connecting portion is detachably coupled to the second portion to secure the voltage converter to the laptop battery, the second interface is electronically connected to the first interface so as to receive the first voltage when the first connecting portion is coupled to the second connecting portion, the first converting unit is configured to convert the first voltage to the second voltage and output the second voltage through the third interface.

11. The power supply device of claim 10, wherein the second voltage is lower than the first voltage.

12. The power supply device of claim 10, wherein the circuit board further comprises a second converting unit and a fourth interface, the second interface, the second converting unit and the fourth interface are electronically connected in series, the second converting unit is configured to convert a third voltage received from the fourth interface to a fourth voltage, and output the fourth voltage through the second interface for charging the laptop battery.

13. The power supply device of claim 12, wherein the circuit board further comprises a selector switch for electronically connecting the second interface and the first converting unit, or electronically connecting the second interface and the second converting unit.

14. The power supply device of claim 12, wherein the fourth voltage is lower than the third voltage.

15. The power supply device of claim 10, wherein the first connecting portion comprises a hook member, the second connecting portion comprises a receiving groove corresponding to the hook member, the voltage converter is secured to the laptop battery by engaging the hook member in the receiving groove.

16. The power supply device of claim 10, wherein when the voltage converter is secured to the laptop battery, the first connecting portion and the second connecting portion are attached together to hide the first interface and the second interface.

17. The power supply device of claim 10, wherein the housing includes an engaging groove and a clamping member, the third interface is receivable in the engaging groove and is configured to be detachably clamped by the clamping member.

18. The power supply device of claim 10, wherein the first connecting portion comprises a receiving cavity, the hook member comprises a hook slidably received in the receiving cavity and a push button fixed to the hook, the hook is slidable out of or into the receiving cavity by manually pushing the push button.
